(19) United States
(12) Patent Application Publication
(10) Pub. No.: US 2008/0081428 A1
(43) Pub. Date: Apr. 3, 2008

(54) Method of Manufacturing Flash Memory Device

(75) Inventor: Young Bok Lee, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/749,237

(22) Filed: May 16, 2007

(30) Foreign Application Priority Data
Sep. 29, 2006 (KR) 2006-96097

(51) Int. Cl. H01L 21/02

(52) U.S. Cl. 438/382; 257/E21.004

(57) ABSTRACT

A method of manufacturing a flash memory device, wherein a first insulating layer is formed over a semiconductor substrate. First insulating layer is etched to form a resistor hole. A first conductive layer is formed to fill the resistor hole and is planarized to form a resistor. A second insulating layer id formed over the first insulating layer including the resistor. A metal contact hole is formed by performing the etching process in the second insulating layer and is connected to the resistor. A second conductive layer is formed to fill the metal contact hole.

### CROSS TO RELATED APPLICATION

The priority of Korean patent application number 10-2006-96097, filed on Sep. 29, 2006, the disclosure of which is incorporated by reference in its entirety, is claimed.

### BACKGROUND OF THE INVENTION

The invention relates, in general, to flash memory devices and, more particularly, to a method of manufacturing a flash memory device, in which a poly resistor is formed simultaneously with the formation of a drain contact plug, improving the characteristics of the device.

As the level of integration in NAND flash memory devices has increased, the size of such devices has decreased. This results in an overlay problem due to the limit of mask pattern formation and the like, influencing the characteristics of the flash memory device. If an integrated design rule is applied when an isolation layer and a polysilicon layer for a floating gate are formed, it is difficult to use a conventional mask pattern for forming a polysilicon layer.

To solve the problem, an improved semiconductor manufacturing method was used. In this method, a gate oxide layer and a first polysilicon layer are formed over a semiconductor substrate. An etch process using a mask pattern is performed to form trenches. An oxide layer is formed to bury the trenches. A Chemical Mechanical Polishing (“CMP”) process and an etch process are performed so that the oxide layer remains within the trenches, forming isolation layers. A dielectric layer and a second polysilicon layer are formed on the entire structure including the isolation layers, and are then patterned to form a date. At this time, the gate is also formed in the peripheral region. The gate formed in the peripheral region is used as a poly resistor.

In the conventional method described above, however, a contact hole must be formed by etching the dielectric layer formed between the first polysilicon layer and the second polysilicon layer. In this case, there is a high possibility that the gate oxide layer formed below the first polysilicon layer may be damaged in the etch process for forming the contact hole. This may result in a short circuit between the semiconductor substrate and the first polysilicon layer, causing malfunction of the device.

Furthermore, the poly resistor is usually used in a pump regulator circuit unit. An impurity is injected into a specific region of a P semiconductor substrate in order to change the concentration. In this case, malfunction may be caused due to variation in an increase of the capacitance value. In addition, at the time of program, erase and read operations in the NAND flash memory device, a specific circuit does not properly distribute voltage in order to transfer the voltage to each terminal. Accordingly, device characteristics can be degraded, and the yield of products may become difficult to secure.

### BRIEF SUMMARY OF THE INVENTION

Accordingly, the invention addresses the foregoing problems, and provides a method of manufacturing a flash memory device in which a poly resistor is formed on an insulating layer in order to prevent the occurrence of a short circuit between a semiconductor substrate and conductive material, and the poly resistor is formed simultaneously the formation of a drain contact plug in order to generate a stable reference voltage without an additional process, improving the characteristics of the device.

According to one aspect, the invention provides a method of manufacturing a flash memory device, including the steps of forming a first insulating layer on an underlying structure in which a gate, a source contact plug, and a drain contact hole are formed, forming a mask pattern for a poly resistor on the first insulating layer, and etching the first insulating layer along the mask pattern, forming a poly resistor hole, removing the mask pattern, and then forming a first conductive layer so that the drain contact hole and the poly resistor hole are filled, polishing the first conductive layer so that the first insulating layer is exposed, and forming a second insulating layer, and forming a metal contact hole in the second insulating layer, and forming a second conductive layer to fill the metal contact hole.

### BRIEF DESCRIPTION OF THE DRAWINGS

FIGS. 1 to 5 are views illustrating a method of manufacturing a flash memory device according to an embodiment of the invention.

### DESCRIPTION OF SPECIFIC EMBODIMENTS

A specific embodiment according to the invention is described below with reference to the accompanying drawings.

FIGS. 1 to 5 are views illustrating a method of manufacturing a flash memory device according to an embodiment of the invention.

FIG. 1 illustrates a peripheral region in which a poly resistor is formed, of a cell region and the peripheral region. Steps before the poly resistor is formed are briefly described below. A first insulating layer 102 is formed over a semiconductor substrate 101 in which a gate (not illustrated) is formed. A source contact plug (not illustrated) is formed in the first insulating layer 102.

Referring to FIG. 2, a second insulating layer 103 is formed over the first insulating layer 102 including the source contact plug. A mask pattern (not illustrated) for forming a drain contact hole is formed on the second insulating layer 103. The drain contact hole (not illustrated) is formed in the first and the second insulating layers 102, 103 by performing an etch process along the mask pattern. A drain contact hole (not illustrated) is formed.

In the peripheral region, a mask pattern (not illustrated) for forming a poly resistor hole A is formed, and an etch process is performed along the mask pattern, forming the poly resistor hole A. The poly resistor hole A is preferably formed to have a length that can include a metal contact to be formed on a subsequent poly resistor. The poly resistor hole A is preferably formed to a depth of about 300 angstroms to about 2000 angstroms. The mask pattern is removed.

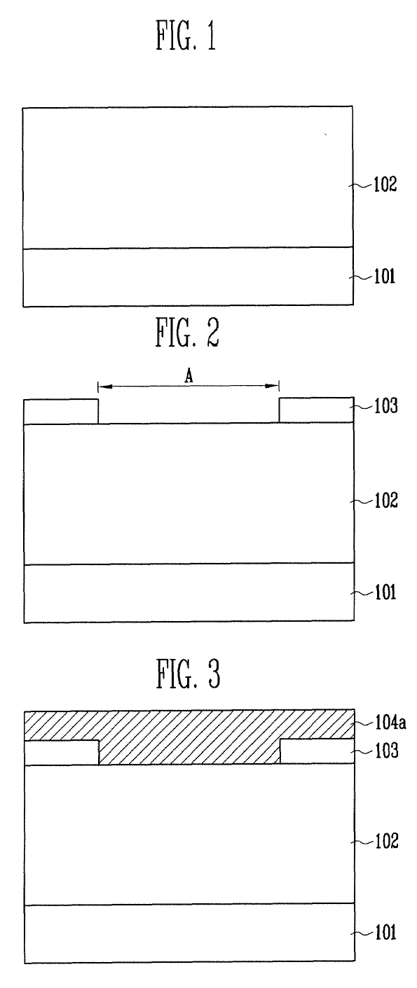

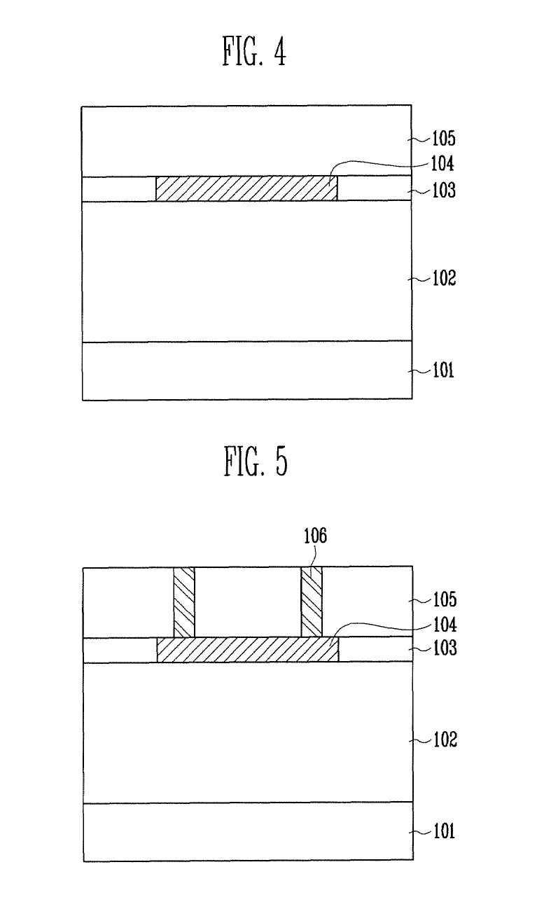

Referring to FIG. 3, a first conductive layer 104a is formed in the drain contact hole (not illustrated) and the poly resistor hole A. The process of forming the first conductive layer 104a is preferably performed at a temperature of about 425° C. to about 625° C. The first conductive layer 104a is preferably formed to a thickness of about 500 angstroms to about 3000 angstroms from the second insulating layer 103.

Referring to FIG. 4, a poly resistor 104 is formed preferably by performing a CMP process at a target of exposing the second insulating layer 103. A third insulating layer 105 is formed over the second insulating layer 102 and the poly resistor 104 including the source and the drain contact plug (not illustrated) and is then polished preferably by performing a CMP process.

Referring to FIG. 5, a mask pattern (not illustrated) for forming a metal contact is formed over the third insulating layer 105. A metal contact hole is formed, preferably by performing an etch process along the mask pattern. A second conductive layer is formed to over the third insulating layer 105 including the metal contact hole. A CMP process is preferably performed on the second conductive layer, forming metal contact plugs 106.

As described above, according to the invention, an insulating layer is formed over the isolation layer, and the poly resistor is then formed. Accordingly, etch margin can be secured when a subsequent metal contact is formed, a desired reference voltage can be formed, and the malfunction of a chip can be prevented.

Although the foregoing description has been made with reference to the specific embodiment, changes and modifications may be made by the person of ordinary skill in the art without departing from the spirit and scope of the invention.

What is claimed is:

1. A method of manufacturing a flash memory device, comprising:
forming a first insulating layer over the semiconductor substrate;
etching the first insulating layer to form a resistor hole;
forming a first conductive layer to fill the resistor hole;
forming a resistor to planarize the first conductive layer;
forming a second insulating layer over the first insulating layer including the resistor;
forming a metal contact hole in the second insulating layer to connect the resistor; and
forming a second conductive layer to fill the metal contact hole.

2. The method of claim 1, wherein the first insulating layer further comprising;
forming a third insulating layer over the semiconductor substrate;
forming a source contact plug in the third insulating layer;
forming the first insulating layer over the third insulating layer including the source contact plug; and
etching the first and the third insulating layer to form a drain contact hole.

3. The method of claim 2, wherein the drain contact hole is filled out the first conductive layer.

4. The method of claim 2, wherein the drain contact hole is filled with the resistor hole by using the first conductive layer.

5. The method of claim 1, comprising forming the poly resistor hole to a depth of about 300 angstroms to about 2000 angstroms.

6. The method of claim 1, wherein the first insulating layer has an etch length sufficient to include a subsequent metal contact.

7. The method of claim 1, comprising forming the poly resistor at a temperature of about 425° C. to about 625° C.

8. The method of claim 1, comprising forming the first conductive layer to a thickness of about 500 angstroms to about 3000 angstroms.

9. The method of claim 1, wherein the resistor is formed with poly silicon.
